(19) United States
(12) Patent Application Publication
(10) Pub. No.: US 2026/0353864 A1
(43) Pub. Date: Nov. 5, 2026

(54) OPTOELECTRONIC DEVICE AND SYSTEM FOR OPTICAL DATA COMMUNICATION

(71) Applicant: AMS-OSRAM INTERNATIONAL GMBH, Regensburg (DE)

(72) Inventors: Adrian Avramescu, Regensburg (DE); Michael Binder, Barbing (DE); Norwin von Maim, Thumhausen/Nittendorf (DE)

(21) Appl. No.: 19/486,021

(22) PCT Filed: May 22, 2024
(86) PCT No.: PCT/EP2024/064147

§ 371 Date: Nov. 19, 2025

(30) Foreign Application Priority Data
May 23, 2023 (DE) 10 2023 113 466.3

(51) Int. Cl. H10H 20/812; H10F 39/10; H10F 77/14; H10H 29/10

(52) U.S. Cl. CPC H10H 20/812; H10F 39/103; H10F 77/1437; H10H 29/10

(57) ABSTRACT

In an embodiment an optoelectronic device includes a continuous first semiconductor layer having a first portion and a laterally displaced second portion, a second semiconductor layer arranged on the first portion, an active region arranged between the first portion and the second semiconductor layer, a top contact element arranged on the second semiconductor layer, and a bottom contact element electrically coupled to the first portion, wherein the first portion, the active region and the second semiconductor layer form a semiconductor layer stack configured to emit light of at least a first wavelength, wherein the second portion is configured to accommodate a detector element and/or is transparent to the light of the first wavelength, and wherein the second layer and the active region is not present above the second portion.

### CROSS-REFERENCE TO RELATED APPLICATIONS

This patent application is a national phase filing under section 371 of PCT/EP2024/064147, filed May 22, 2024, which claims the priority of German patent application no. 10 2023 113 466.3, filed May 23, 2023, each of which is incorporated herein by reference in its entirety.

### TECHNICAL FIELD

The present invention concerns an optoelectronic device, an arrangement of optoelectronic devices and a system for optical data communication. The present invention further concerns a method for operating an optoelectronic device and for operating a system for optical data communication.

### BACKGROUND

Today's Internet relies on large data centres. However, their high-power consumption poses problems to ensure their operation with purely sustainable energy sources. Most of the power is consumed not for computations, but for data transmission over short distances (<<10 m) : CPU to GPU, server to server, rack to rack.

Currently, short-range data communication is either done electrically, mainly by copper (Cu) or aluminium (Al) feed lines and wires (intra-chip or within mainboard), or optically by the combination of near infrared (NIR) vertical-cavity surface-emitting lasers (VCSEL) with optical fibres. The metals however cause electrical power losses due to their specific resistance and the VCSELs on the other hand need a certain threshold current (Iₜₕ) to start laser emission, typically in the mA regime. Together with the necessary forward voltage this threshold current Iₜₕ defines a dissipated (electrical) power of some mW.

To reduce the power for optical short range data transmission there are activities on using μ-LEDs to tackle the challenge of high power consumption. μ-LEDs namely have the advantage of a possible operation with low currents (1-500 A per pixel), which is many factors lower as for lasers, e.g. VCSELs, and they don't need a (lasing-)threshold, which needs to be passed. In addition, μ-LEDs have a small footprint (<5 μm possible) and can be transferred to backplane wafers by common display technologies, thus a high parallelization while transferring the μ-LEDs can be achieved further reducing the power consumption while manufacturing the hardware.

The use of small optoelectronic components such as μ-LEDs for optical data communication has thus major benefits to, e.g., VCSEL technology due to better scalability and lower current operation, saving energy in particular for data transmission over short and midrange distances.

The use of small optoelectronic components such as μ-LEDs however requires, besides a high quantum efficiency, a very fast “switchability” of the emitters in order to allow for high data rates. One limitation with respect to this is radiative recombination lifetime, limiting the rise and fall time of light emission when modulating or turning on/off the μ-LED. This effect in particular plays a great role when using μ-LEDs due to their large surface to volume ratio.

Currently known approaches to decrease radiative recombination lifetime include for example background doping (e.g. in the QW barriers) in order to increase charge carrier density for certain charge carrier types, the use of Quantum dots, and/or to try and achieve a high current density.

These methods can however only improve the performance of the optoelectronic components to a certain extent.

### SUMMARY

Embodiments provide an optoelectronic component as well as a system for optical data communication that counteracts at least some of the disadvantages mentioned.

Embodiments provide an optoelectronic device as well as a system using such optoelectronic devices by means of which via a single optical fibre data for optical data communication can be sent back and forth within the single optical fibre. This can be done by using an integrated optoelectronic device comprising a monolithically grown μ-LED on a first portion of a semiconductor layer as well as arranging a μ-Detector on, above or below a second portion of the same semiconductor layer adjacent to the first portion. The second portion thereby acts as kind of a placeholder for later arranging the μ-Detector on, above or below the second portion of the semiconductor layer. Depending on the operation mode, the optoelectronic devices can be used either as emitters and/or as detectors allowing an “universal” use of the same. By this the footprint of such a system can be reduced.

Embodiments provide an integrated optoelectronic device with an emitting portion and a detecting portion, whereby the emitting portion is monolithically grown as a semiconductor layer stack and the detector portion is at least provided at wafer level, namely in the form of a connection surface or in the form of a window formed by the same as one of the semiconductor layers of the semiconductor layer stack. By this a separate detector can afterwards be placed exactly where it was intended to be together with the semiconductor layer stack forming a combined and integrated μ-LED and μ-Detector.

In a first embodiment an optoelectronic device, in particular combined μ-LED and μ-Detector, is provided. The optoelectronic device comprises a continuous first semiconductor layer having a first portion and a laterally displaced second portion, a second semiconductor layer arranged on the first portion, and an active region arranged between the first portion and the second semiconductor layer. The optoelectronic device further comprises a top contact element arranged on the second semiconductor layer and a bottom contact element electrically coupled to the first portion. The first and the second semiconductor layer thereby comprise a doping of a different conductivity type and the first portion, the active region and the second semiconductor layer form a semiconductor layer stack configured to emit light of at least a first wavelength when applying a supply voltage to the top and bottom contact element. Hence the semiconductor layer stack of the first portion the active region and the second semiconductor layer from an emitter portion of the optoelectronic device. The second portion on the other hand is configured to accommodate a separate detector element and/or is substantially transparent to light of the first wavelength or a second wavelength to be detected, to transmit light of a first wavelength or a second wavelength to a detector element arranged below the second portion. The second portion together with a separate detector element thus forms a detector portion of the optoelectronic device.

In some embodiments, the optoelectronic device is a combined μ-LED and μ-Detector. A such combined μ-LED and μ-Detector can in particular be a device with edge lengths smaller than 100 μm, smaller than 50 μm, smaller than 20 μm, smaller than 10 μm or smaller than 5 μm being configured to emit and detect light of a desired wavelength.

The semiconductor layer stack can be of any shape, for example a truncated pyramidal shape with angled side surfaces or a truncated cylindrical shape with angled side surfaces. Such angled side surfaces can for example result from a mesa etching process. These exemplary embodiments are however not to be understood in a limiting way but just as possible embodiments. Any other arrangements, shapes and cross sections are also possible.

In some embodiments, the second layer and the active region are removed to form the second portion of the first semiconductor layer. The second portion in turn is free/not covered of/by the active region and the second semiconductor layer. For example, the first semiconductor layer, the second semiconductor layer and the active region between the first and second semiconductor layer can be grown over a large area and then removed again in areas forming the first and the second portion. However, it is also conceivable to grow the second semiconductor layer and the active region only on the first portion of the first semiconductor layer but not the second portion.

In some embodiments, the optoelectronic device further comprises a detector element arranged on the second portion and in particular on a protrusion of the first semiconductor layer forming the second portion. The second portion in particular comprises a protrusion of the first semiconductor layer on which the detector element, such as for example a photodetector, is arranged. In between the layer stack and the protrusion, a gap or recess can be formed in the first semiconductor layer, thus the first portion and the second portion and the emitter portion and the detector portion respectively are spaced from each other.

In some embodiments, a short-period superlattice (SPSL) layer is arranged between the first semiconductor layer and the active region and/or between the first semiconductor layer and the detector element or is part of the detector element. By means of such a layer tensions between the first semiconductor layer and an adjacent layer/component can be reduced.

In some embodiments, the optoelectronic device further comprises a carrier substrate, in particular a CMOS backplane. The carrier substrate is arranged above the first semiconductor layer or on top of the second semiconductor layer and is electrically coupled to the top and/or bottom contact element. The carrier substrate can for example comprise a supply circuit being in electric contact with the top and/or bottom contact element as well as with the detector element. The carrier substrate can for example be in form of a CMOS element or a portion of a CMOS wafer.

In some embodiments, the carrier substrate is bonded to extensions of the bottom and/or top contact element or is directly bonded to either the bottom or top contact element.

The carrier substrate can however also be monolithically integrated with the first semiconductor layer and the semiconductor layer stack as well as with the contact elements. It is also conceivable that the optoelectronic device comprises no carrier substrate and is at a later stage placed on a respective carrier substrate.

In some embodiments, a detector element is arranged on the carrier substrate adjacent to the second portion such that the detector element is arranged between the carrier substrate and the second portion. In such a case the second portion is in particular formed as a window or opening configured to transmit the light of the at least first wavelength or a second wavelength incident on the second portion to the detector element below the second portion.

In some embodiments, the detector element is configured to detect the light of the first wavelength or of a second wavelength incident on the detector element. The detector element can for example be a high speed detector, a photodiode, an avalanche photodiode (APD), or a metal-semiconductor-metal (MSM) photodetector. Together with the second portion of the first semiconductor layer the detector element forms a detector portion of the optoelectronic device.

In some embodiments, the optoelectronic device further comprises contact vias through the second portion of the first semiconductor layer to provide contact elements for electrically contacting a detector element arranged on the second portion. Hence by means of the contact vias the detector element can be electrically contactable from the other side of the first semiconductor layer namely the one that points away from the detector element.

At least one of the top or the bottom contact element can for example be substantially transparent to light of the first wavelength. In particular the top or the bottom contact element can form a light emitting area of the optoelectronic device through which light generated in the active region is outcoupled from the optoelectronic device. Such a substantially transparent contact element can for example be formed of a transparent conductive oxide (TCO) such as for example Indium Tin Oxide (ITO). The light emitting area can be formed by either the top contact element or the bottom contact element itself or further structure(s)/element(s) as described later herein.

In some embodiments, the other one of the top and bottom contact element not being substantially transparent can comprise a reflective material layer covering the underlying layer of the first and second semiconductor layer. In case of the top contact element the reflective material layer can cover the second semiconductor layer opposite the active region or in case of the bottom contact element the reflective material layer can cover the first portion of the semiconductor layer opposite the active region. This allows a directional radiation of generated light in the direction of the light emitting area and a more efficient outcoupling of the generated light through the light emitting area.

In some embodiments, the first semiconductor layer at least in the second portion is substantially transparent to light of the first wavelength. The second portion can in particular form a window/light incident area of the optoelectronic device for light incident on the second portion to be detected by an underlying detector element. The second portion can however also comprise an opening through the first semiconductor layer, which is optionally filled with an in particular transparent filler material. In such a case the opening or the optional filler material can form a light incident area of the optoelectronic device for light incident on the second portion to be detected by an underlying detector element.

In some embodiments, the optoelectronic device further comprises an optical barrier arranged on the first semiconductor layer between the first portion and the second portion, wherein the optical barrier prevents direct emission of light of at least the first wavelength from the active region toward the detector element. The optical barrier can therefore for example be reflective or absorbing for light of the first wavelength and can be of such a height that extending from the first semiconductor layer it protrudes the semiconductor layer stack or comprises at least an equal height.

In some embodiments, the optoelectronic device further comprises an outcoupling structure on the top contact element and/or the second semiconductor layer opposite the first semiconductor layer or an outcoupling structure on the bottom contact element and/or the first semiconductor layer opposite the second semiconductor layer. The outcoupling structure for example forms a light emitting area of the optoelectronic device. The outcoupling structure can for example be a surface roughening of the top or bottom contact element. In this way an outcoupling of light from the optoelectronic device can be improved, as well as a directionality of the outcoupled light can be improved. In addition, an in-coupling of light into an adjacent optical fibre can by this be improved.

In some embodiments, the optoelectronic device further comprises an optical element on the top contact element and/or the second semiconductor layer opposite the first semiconductor layer or on the bottom contact element and/or the first semiconductor layer opposite the second semiconductor layer. The optical element can for example be a μ-lens or a photonic structure. In this way an outcoupling of light from the optoelectronic device can be improved, as well as a directionality of the outcoupled light can be improved. In addition, an in-coupling of light into an adjacent optical fibre can by this be improved.

In some embodiments, the optoelectronic device comprises a plurality of emitter portions and a detector portion, wherein the emitter portions each comprise a portion of the active region and the second layer. The emitter portions can for example be spaced from each other by a gap. By this, a redundancy between the emitters can be achieved in case of one or several emitter portions fail.

In some embodiments, optoelectronic device(s) according to the proposed principle can be processed as individual elements, capable of being for example transfer printed or transferred onto a carrier substrate. In some embodiments, optoelectronic devices according to the proposed principle can however also be processed as an array/a plurality of optoelectronic devices arranged adjacent on a carrier substrate forming an arrangement.

In a further embodiment it is thus provided an arrangement comprising a carrier substrate and a plurality of optoelectronic devices according to some embodiments of the proposed principle arranged adjacent to each other on a common carrier substrate. In some embodiments, the optoelectronic devices are thereby arranged in an array in rows and columns.

The integration of emitters and detectors into a combined optoelectronic device such as described above allows fabrication of a compact and well-aligned arrangement of optoelectronic devices. Furthermore, very short connections to a carrier substrate such as a CMOS driver by using vias for vertical stacking can be achieved.

In a further embodiment it is provided a system for optical data communication comprising a first arrangement of optoelectronic devices and a second arrangement of optoelectronic devices. The optoelectronic devices of the first arrangement are thereby optically coupled with a respective optoelectronic device of the second arrangement to transmit optical data. Each optoelectronic device of the first and second arrangement thereby comprises an emitter and a detector portion such that via one single optical data can be transmitted back and forth between the two arrangements. At least one of the first and second arrangement is thereby an arrangement according to some of aforementioned embodiments.

In some embodiments, the optoelectronic devices of the first arrangement are configured to emit light of a first wavelength and the optoelectronic devices of the second arrangement are configured to detect the light of the first wavelength emitted by the respective optoelectronic device of the first arrangement. Thus, the first arrangement is configured to send optical data and the second arrangement is configured to detect optical data. In addition, the optoelectronic devices of the second arrangement are configured to emit light of a second wavelength and the optoelectronic devices of the first arrangement are configured to detect the light of the second wavelength emitted by the respective optoelectronic device of the second arrangement. Thus, the second arrangement is also configured to send optical data and the first arrangement is configured to also detect optical data. For optical data communication it is thus only one arrangement configured to emit and detect optical data necessary on each side of the communicating objects and a communication between the communicating objects is realized by sending and emitting data at different points of time or in case of the first and second wavelength being different by sending and detecting data with different wavelengths at the same time. The optoelectronic devices of the first arrangement are therefore for example be configured to emit at a first point of time light of a first wavelength and the optoelectronic devices of the second arrangement are configured to detect the light of the first wavelength emitted by the respective optoelectronic device of the first arrangement at the first point of time. In addition the optoelectronic devices of the second arrangement are configured to emit at a second point of time light of the second wavelength and the optoelectronic devices of the first arrangement are configured to detect the light of the second wavelength emitted by the respective optoelectronic device of the second arrangement at the second point of time. However, sending and detecting in both directions is also possible at the same time with different wavelengths.

In some embodiments, the first and second wavelength are substantially the same, and thus the first and second arrangement comprise substantially the same optoelectronic devices. In some embodiments, the first and second wavelength are however different from each other. In latter case, above each detector portion of the optoelectronic devices of the first arrangement a first wavelength filter can be arranged and above each detector portion of the optoelectronic devices of the second arrangement a second wavelength filter can be arranged. The first wavelength filter can thereby be configured to transmit light of the second wavelength but block light of the first wavelength and the second wavelength filter can thereby be configured to transmit light of the first wavelength but block light of the second wavelength.

In a further embodiment it is provided a method for operating a system according to some embodiments of the proposed principle. The method comprises the steps:
emitting light of a first wavelength by means of a first optoelectronic device of the first arrangement;
coupling the light of the first wavelength into a first optical fibre;
transmitting the light of the first wavelength to a respective first optoelectronic device of the second arrangement;
coupling the light of the first wavelength into the first optoelectronic device of the second arrangement; and
detecting the light of the first wavelength by means of the first optoelectronic device of the second arrangement.

In some embodiments, the method further comprises the steps:
emitting light of a second wavelength by means of the first optoelectronic device of the second arrangement;
coupling the light of the second wavelength into the first optical fibre;
transmitting the light of the second wavelength to the first optoelectronic device of the first arrangement;
coupling the light of the second wavelength into the first optoelectronic device of the first arrangement; and
detecting the light of the second wavelength by means of the first optoelectronic device of the first arrangement.

### BRIEF DESCRIPTION OF THE DRAWINGS

Further embodiments and embodiments in accordance with the proposed principle will become apparent in relation to the various embodiments and examples described in detail in connection with the accompanying drawings in which:

FIGS. 1A and 1B each show a side view of an embodiment of an optoelectronic device in accordance with some embodiments of the proposed principle;

FIGS. 2A and 2B each show a side view of further embodiments of an optoelectronic device in accordance with some embodiments of the proposed principle;

FIGS. 3A and 3B each show a side view of further embodiments of an optoelectronic device in accordance with some embodiments of the proposed principle;

FIG. 4 shows a top view of further embodiment of an optoelectronic device in accordance with some embodiments of the proposed principle;

FIG. 5 shows a side view of an embodiment of an optoelectronic arrangement in accordance with some embodiments of the proposed principle;

FIG. 6 shows an embodiment of a system for optical data communication in accordance with some embodiments of the proposed principle; and

FIG. 7 shows another embodiment of a system for optical data communication in accordance with some embodiments of the proposed principle.

### DETAILED DESCRIPTION OF ILLUSTRATIVE EMBODIMENTS

The following examples disclose various embodiments and their combinations according to the proposed principle. The embodiments and examples are not always to scale. Likewise, different elements can be displayed enlarged or reduced in size to emphasize individual embodiments. It goes without saying that the individual embodiments of the examples shown in the figures can be combined with each other, without this contradicting the principle according to the invention. Some embodiments show a regular structure or form. It should be noted that in practice slight differences and deviations from the ideal form may occur without, however, contradicting the inventive idea.

In addition, the individual figures and embodiments are not necessarily shown in the correct size, nor do the proportions between individual elements have to be essentially correct. Some embodiments are highlighted by showing them enlarged. However, terms such as “above”, “over”, “below”, “under” “larger”, “smaller” and the like are correctly represented with regard to the elements in the figures. So it is possible to deduce such relations between the elements based on the figures.

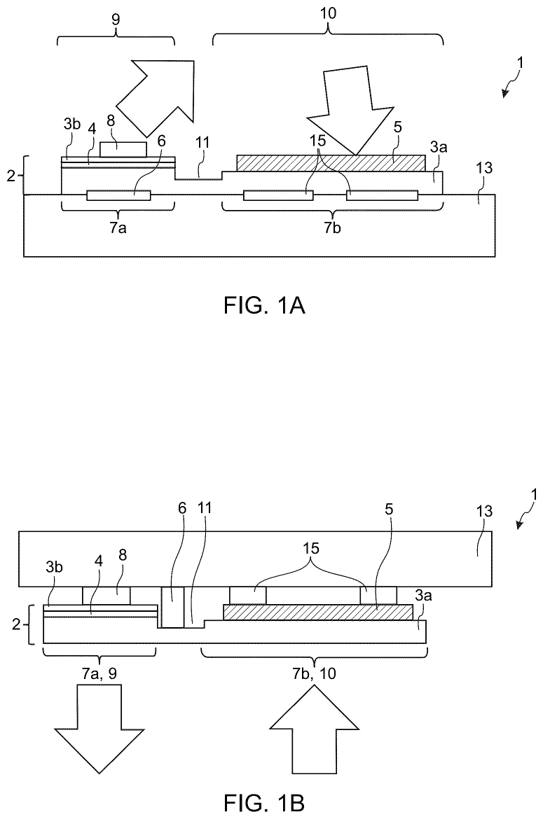

FIG. 1A shows a first embodiment of an optoelectronic device 1 in accordance with some embodiments of the proposed principle. The optoelectronic device 1 comprises a first semiconductor layer 3a having a first portion 7a and a laterally displaced second portion 7b divided by a small gap 11. On the first portion 7a a second semiconductor layer 3b as well as an active region 4 between the first portion 7a and the second semiconductor layer 3b are arranged together forming a semiconductor layer stack 2. The first and the second semiconductor layer 3a, 3b comprise a doping of a different conductivity type such that together with the active region 4 and a top contact element 8 arranged on the second semiconductor layer 3b and a bottom contact element 6 electrically coupled to the first portion 7a the semiconductor layer stack 2 is configured to emit light of at least a first wavelength when applying a supply voltage to the top and bottom contact element 8, 6.

In addition, the second portion 7b is configured to accommodate a detector element 5 which is arranged on a protrusion of the first semiconductor layer 3a forming the second portion 7b. By means of the bottom contact element 6 as well as contact pads 15 arranged on the first semiconductor layer 3a opposite the second portion 7b, the detector element as well as the semiconductor layer stack 2 is electrically connected to a carrier substrate 13 in form of a CMOS backplane. The top contact element 8 can for example be connected to the backplane by means of a contact via through the first semiconductor layer 3a or b means of an interconnect extending from the top contact element 8 to the carrier substrate 13. In addition, the optoelectronic device 1 can comprise not shown contact vias through the second portion 7b to provide an electrical connection between the contact pads 15 and the detector element 5. By means of the carrier substrate 13, the emitter as well as the detector portion 9, 10 and thus the optoelectronic device 1 can be controlled.

During epitaxial growth of the semiconductor layer stack 2 the second portion 7b of the first semiconductor layer 3a can in particular be provided to later be able to arrange the detector element 5 as an integral part of the optoelectronic device 1 on the second portion 7b. By this a very complex and space saving integrated component can be provided which can for example be used as an optoelectronic device 1 for data communication.

FIG. 1B shows an embodiment of an optoelectronic device 1 in which in comparison to the one shown in FIG. 1A the carrier substrate 13 is arranged on the opposing side of the detector element 5 and the semiconductor layer stack 2. The carrier substrate 13 is in this case directly bonded to the top contact element 8 and to an extension of the bottom contact element 6 as well as contact pads 15 arranged on the detector element 5 directly. To allow light generated within the semiconductor layer stack 2 being emitted from the optoelectronic device 1 the first semiconductor layer 3a and in particular the first portion 7a need to be substantially transparent at least for the light generated within the semiconductor layer stack 2. The same applies to the detector portion 10. Hence, the first semiconductor layer 3a and in particular the second portion 7b needs to be substantially transparent at least for the light to be detected by the detector element 5.

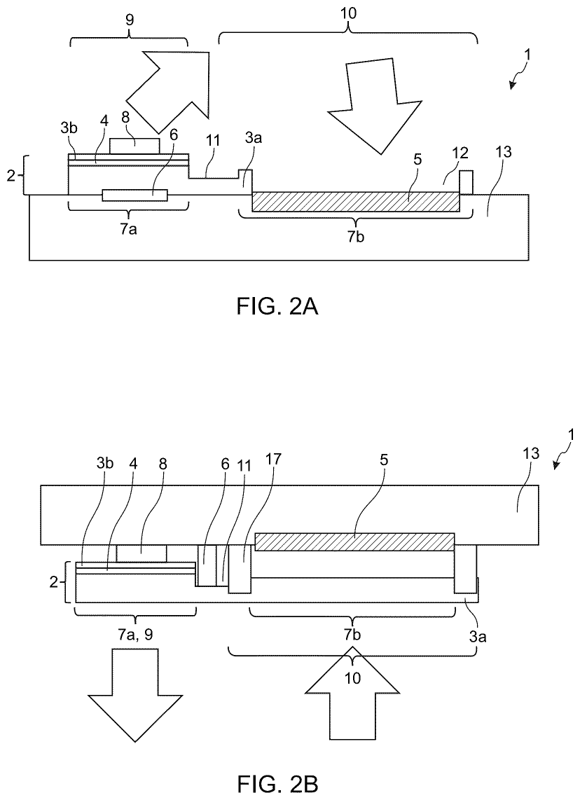

FIGS. 2A and 2B each shown an embodiment of an optoelectronic device 1 in which in comparison to the ones shown in FIGS. 1A and 1B the detector element is not arranged on the first semiconductor layer 3a but on or integrated into the carrier substrate 13. The second portion 7b of the first semiconductor layer 3a in this case acts as substantially transparent window or opening 12 for the detector element arranged above the detector element 5 with the detector element 5 being arranged between the second portion 7b and the carrier substrate 13.

In case of the embodiment of FIG. 2A the second portion 7b of the first semiconductor layer 3a comprises opening 12 through which light is incident on the detector element 5 to be detected. The first semiconductor layer 3a can therefore already be provided on wafer lever to comprise the opening 12 in which or below which the detector element 5 is at a later point of time arranged. The opening 12 can then or already on wafer level be filled by a transparent filler material.

In FIG. 2B on the other hand the second portion comprises a transparent window with the transparent window being formed of the material of the first semiconductor layer 3a being substantially transparent to light to be detected by the detector element 5. To keep the right distance between the second portion 7b and the detector element 5 as well as to increase the light detection efficiency of the optoelectronic device 1, an optical barrier 17 is arranged between the semiconductor layer stack 2 and the detector element 5 surrounding the detector element 5 in a circumferential direction. The optical barrier 17 is attached to the first semiconductor layer 3a and the carrier substrate 13 and is in particular arranged between the first and the second portion 7a, 7b to provide a direct emission of light from the semiconductor layer stack 2 to the detector element 5.

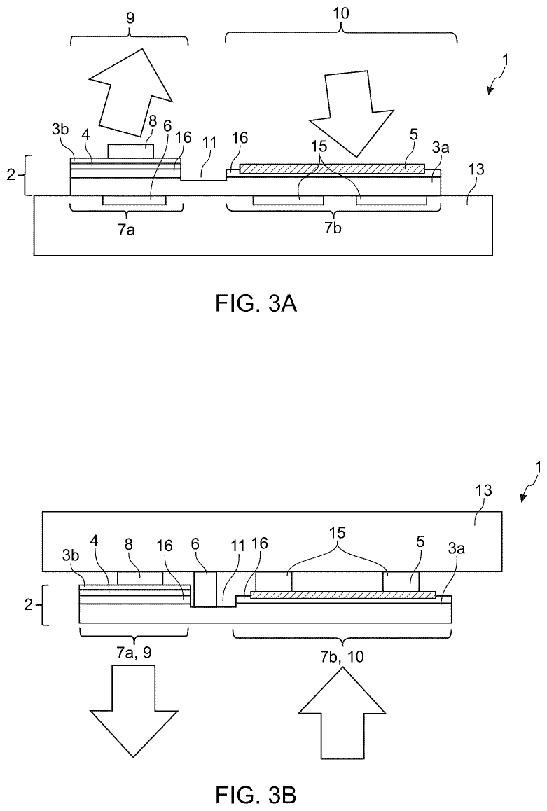

The embodiments shown in FIGS. 3A and 3B in addition to the embodiments shown in FIGS. 1A and 1B comprise a short-period superlattice (SPSL) layer 16 arranged between the first semiconductor layer 3a and the active region 4 as well as between the first semiconductor layer 3a and the detector element 5. By means of such a layer, the epitaxially strains between the first semiconductor layer and an adjacent layer/component can be reduced. In addition, the detector element 5 is formed as a lateral detector, for example a metal insulator semiconductor (MIS) lateral detector. By this, the detector element 5 can be manufactured by a simplified fabrication process since the semiconductor layers are already in place and contact pads for electrically contacting the detector element can be grown together with one of the steps already needed for growing the contact elements of the emitter portion. SPSL can for example be based on Ga(In)N/InGaN layers with an indium-content of for example <20% atomic, with for example a periodicity from 2 nm up to 10 nm and with for example a total thickness of 20 nm to 500 nm.

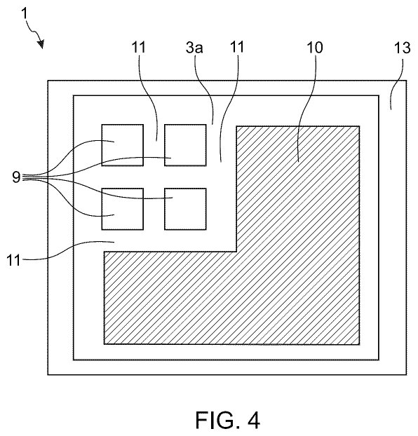

FIG. 4 shows an exemplary top view of the embodiment of the optoelectronic device 1. The optoelectronic device 1 comprises four emitter portions 9 in one “corner” of the optoelectronic device 1 each divided by gaps 11 as well as one detector portion 10 extending along the opposing sides of the “corner” of the optoelectronic device 1. By this, a redundancy between the emitter portions 9 can be achieved in case of one or several emitter portions fail. The number, design and arrangement of the emitter portions 9 shown is however to be understood as only an example and can vary.

For example the area ratio between emitter and detector portions of an optoelectronic device can be in the range of detector (D) vs. emitter (E)=(100×100/1×1)=10000 down to D/E=(20×20/2'2)=100 or even down to D/E=10 as the lowest limit, whereas the numbers (Y×Y/Z×Z) give exemplary values of the size of a surface area of the emitter and detector portion in μm.

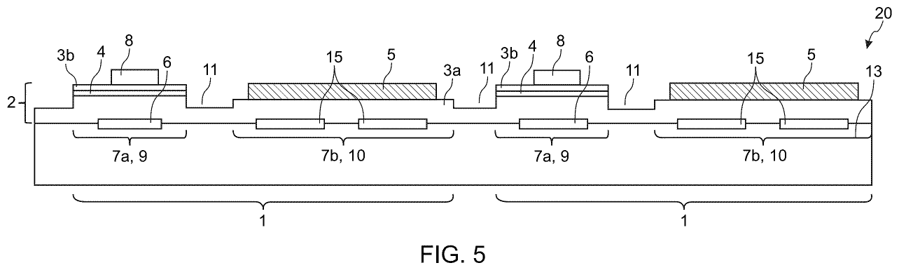

FIG. 5 shows an arrangement 20 in accordance with some embodiments of the proposed principle. The arrangement comprises a plurality of optoelectronic devices 1 as shown in FIG. 1A arranged adjacent to each other on a common carrier substrate 13. In the embodiment shown, exemplarily two optoelectronic devices 1 are arranged on the common carrier substrate, however the number two is to be understood only as exemplarily. For example, a plurality of optoelectronic devices 1 can be arranged in an array in rows and columns on the common carrier substrate 13. The common carrier substrate can thereby for example be a CMOS wafer providing the necessary supply circuit for operating the optoelectronic devices 1.

An exemplary method for manufacturing such an arrangement 20 can for example comprise the steps:
providing the bottom contact elements 6;
providing the first semiconductor layer 3a;
providing the active region 4;
providing the second semiconductor layer 3b;
structuring the semiconductor layer stack to receive the emitter portions 9/first portions 7a and the detector portions 10/second portions 7b;
providing the top contact element 8 on the second semiconductor layer 3b;
providing the detector elements on the second portions 7b;
bonding the carrier substrate to the bottom contact elements 6.

Aforementioned steps are however understood to be exemplary and can vary in their order and/or several steps can be dispensed with/are optional.

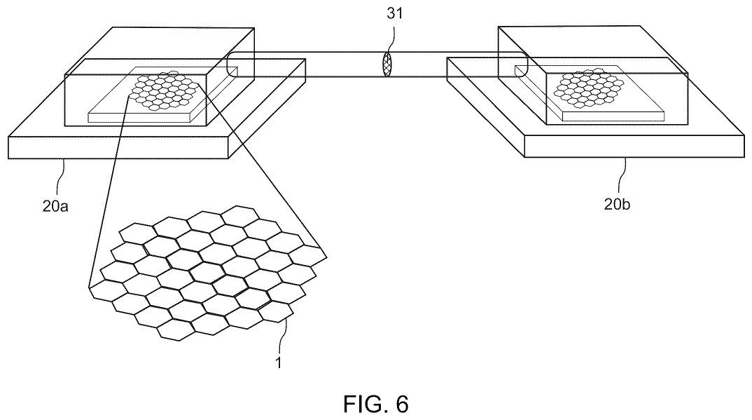

FIG. 6 shows a first embodiment of a system 30 for optical data communication in accordance with some embodiments of the proposed principle. The system 30 comprises a first arrangement 20a of optoelectronic devices 1, a second arrangement 20b of optoelectronic devices 1 and a multicore fibre optically coupling the first and second arrangement. The optoelectronic devices 1 of the first arrangement 20a are optically coupled with a respective optoelectronic device 1 of the second arrangement 20b via an optical fibre 31 of the multicore fibre. As the optoelectronic devices are configured to both emit and detect light of a desired wavelength, only one arrangement of optoelectronic devices is necessary on each side of the communicating objects and a back and forth communication can be provided by the system 30.

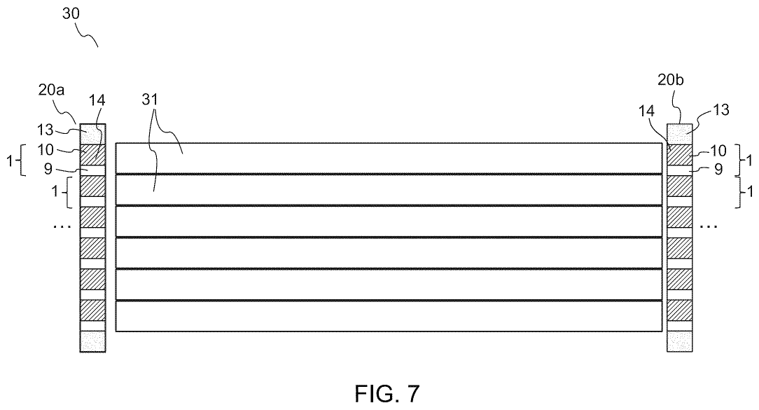

FIG. 7 shows another view of a system 30 of for optical data communication in accordance with some embodiments of the proposed principle. In the system 30, optoelectronic devices 1 are together arranged on a carrier substrate 13 each comprising an emitter and a detector portion 9, 10. Each optoelectronic device is optically coupled to only one optical fibre 31. Above each of the detector portions 10 of the optoelectronic devices 1, a wavelength filter 14 is arranged being transmissive of at least the light emitted by the emitter portion 9 of the respective optoelectronic device 1 of the opposing arrangement. By this it can be ensured that only light of the respective wavelength is transmitted to the detector element of the respective optoelectronic device.

1.-24. (canceled)

25. An optoelectronic device comprising:
a continuous first semiconductor layer having a first portion and a laterally displaced second portion;
a second semiconductor layer arranged on the first portion;
an active region arranged between the first portion and the second semiconductor layer;
a top contact element arranged on the second semiconductor layer; and
a bottom contact element electrically coupled to the first portion,
wherein the first and second semiconductor layers comprise a doping of a different conductivity type,
wherein the first portion, the active region and the second semiconductor layer form a semiconductor layer stack configured to emit light of at least a first wavelength when a supply voltage is applied to the top and bottom contact elements,
wherein the second portion is configured to accommodate a detector element and/or is transparent to the light of the first wavelength, and
wherein the second layer and the active region is not present above the second portion.

26. The optoelectronic device according to claim 25, wherein a protrusion of the first semiconductor layer forms the second portion, and wherein the detector element is arranged on the protrusion.

27. The optoelectronic device according to claim 25, further comprising a short-period superlattice (SPSL) layer arranged between the first semiconductor layer and the active region and/or between the first semiconductor layer and the detector element, or wherein the SPSL layer is part of the detector element.

28. The optoelectronic device according to claim 25, further comprising a carrier substrate, wherein the carrier substrate is electrically coupled to the top contact element and/or the bottom contact element.

29. The optoelectronic device according to claim 28, wherein the detector element is arranged on the carrier substrate adjacent to the second portion.

30. The optoelectronic device according to claim 28, wherein the carrier substrate comprises a supply circuit in electric contact with the top contact element and the bottom contact element.

31. The optoelectronic device according to claim 25, wherein the top contact element or the bottom contact element is transparent to the light of the first wavelength.

32. The optoelectronic device according to claim 25, wherein the first semiconductor layer is transparent to the light of the first wavelength.

33. The optoelectronic device according to claim 25, wherein the second portion comprises an opening through the first semiconductor layer optionally filled with a transparent filler material.

34. The optoelectronic device according to claim 25, further comprising an optical barrier arranged on the first semiconductor layer between the first portion and the second portion, wherein the optical barrier is configured to prevent direct emission of the light of the first wavelength from the semiconductor layer stack toward the detector element.

35. The optoelectronic device according to claim 25, further comprising an outcoupling structure arranged on the semiconductor layer stack, and/or an optical element on the semiconductor layer stack, and/or contact vias through the second portion to provide contact elements for electrically contacting the detector element arranged on the second portion.

36. The optoelectronic device according to claim 25, wherein the detector element is configured to detect the light of the first wavelength.

37. An arrangement comprising:
a plurality of optoelectronic devices according to claim 25 arranged adjacent to each other on a common carrier substrate.

38. The arrangement according to claim 37, wherein the optoelectronic devices are arranged in an array in rows and columns and/or wherein the optoelectronic devices are optically isolated from each other.

39. A system for optical data communication comprising:
a first arrangement of optoelectronic devices and a second arrangement of optoelectronic devices,
wherein the optoelectronic devices of the first arrangement are optically coupled with a respective optoelectronic device of the second arrangement,
wherein each optoelectronic device of the first and second arrangements comprises an emitter and a detector portion, and
wherein at least one of the first arrangement or the second arrangement is the arrangement according to claim 37.

40. The system according to claim 39,
wherein the optoelectronic devices of the first arrangement are configured to emit the light of the first wavelength and wherein the optoelectronic devices of the second arrangement are configured to detect the light of the first wavelength emitted by the respective optoelectronic device of the first arrangement,
wherein the optoelectronic devices of the second arrangement are configured to emit light of a second wavelength and wherein the optoelectronic devices of the first arrangement are configured to detect the light of the second wavelength emitted by the respective optoelectronic device of the second arrangement.

41. The system according to claim 40, wherein the first and second wavelength are different from each other.

42. The system according to claim 41,
wherein above each detector portion of the optoelectronic devices of the first arrangement a first wavelength filter is arranged and wherein above each detector portion of the optoelectronic devices of the second arrangement a second wavelength filter is arranged, and
wherein the first wavelength filter is configured to transmit light of the second wavelength but block light of the first wavelength and wherein the second wavelength filter is configured to transmit light of the first wavelength but block light of the second wavelength.

43. A method for operating the system according to claim 39, the method comprising:
emitting light of the first wavelength by a first optoelectronic device of the first arrangement;
coupling the light of the first wavelength into a first optical fibre;
transmitting the light of the first wavelength to a respective first optoelectronic device of the second arrangement;
coupling the light of the first wavelength into the first optoelectronic device of the second arrangement; and
detecting the light of the first wavelength by the first optoelectronic device of the second arrangement.

44. The method according to claim 43, further comprising:
emitting light of a second wavelength by the first optoelectronic device of the second arrangement;
coupling the light of the second wavelength into the first optical fibre;
transmitting the light of the second wavelength to the first optoelectronic device of the first arrangement;
coupling the light of the second wavelength into the first optoelectronic device of the first arrangement; and
detecting the light of the second wavelength by the first optoelectronic device of the first arrangement.
